(19) United States
(12) Patent Application Publication
(10) Pub. No.: US 2007/0194295 A1
(43) Pub. Date: Aug. 23, 2007

(54) Semiconductor device of Group III nitride semiconductor having oxide protective insulating film formed on part of the active region

(75) Inventors: Katsunori Nishii, Osaka (JP); Yoshito Ikeda, Osaka (JP); Kaoru Inoue, Shiga (JP)

Correspondence Address: MCDERMOTT WILL & EMERY LLP, 600 13TH STREET, NW, WASHINGTON, DC, 20005-3096, US

(73) Assignee: Matsushita Electric Industrial Co., Ltd., Osaka (JP)

(21) Appl. No.: 11/785,799

(22) Filed: Apr. 20, 2007

Related U.S. Application Data
(62) Division of application No. 10/437,228, filed on May 14, 2003.

(30) Foreign Application Priority Data
May 30, 2002 (JP) 2002-157830

(51) Int. Cl. H01L 29/06

(52) U.S. Cl. 257/11

(57) ABSTRACT

An active region formed of a Group III nitride semiconductor is formed on a substrate. Then, an electrode is formed on the active region and a protective insulating film is formed on a part of the active region located in the peripheral portion of the electrode by oxidizing the Group III nitride semiconductor.

### BACKGROUND OF THE INVENTION

The present invention relates to a semiconductor device using a gallium nitride (which will be herein referred to as “GaN”) base semiconductor expressed by the general formula of In_{X}Al_{Y}Ga_{1-X-Y}N (0≦X≦1, 0≦Y≦1, 0≦X+Y≦1), and more particularly, relates to a semiconductor device including an insulating oxide film formed by oxidizing a GaN base semiconductor.

GaN base semiconductors (i.e., Group III nitride semiconductors), such as GaN, AlGaN, InGaN, and InAlGaN, have a band structure in which an electron makes a direct interband transition and a band gap varies between about 1.95 eV and about 6 eV. With this structure, GaN base semiconductors are regarded as promising materials for light emitting devices, such as laser diodes. In recent years, research and development has been actively carried out on semiconductor laser diodes that can emit light with a wavelength in the blue-violet region, in particular, in order to achieve high-density information processors. Moreover, GaN attracts attentions as a promising material for high frequency power devices because of its high breakdown electric field intensity, high heat conductivity, and high electron saturation velocity. More specifically, with an electric field intensity of 1×10⁵ V/cm, the AlGaN/GaN heterojunction structure has an electron saturation velocity more than twice as high as that of GaAs. This structure is therefore expected to achieve a further miniaturized device operable at a high frequency.

GaN base semiconductors exhibit n-type characteristics when they are doped with an n-type dopant, such as Si or Ge, and attempts have been therefore made to make practical applications of GaN base semiconductors to field effect transistors (FETs) or the like. There also have been attempts to apply GaN base semiconductors to LEDs, semiconductor laser diodes, and like devices, since the semiconductors exhibit p-type characteristics when doped with a p-type dopant such as Mg, Ba or Ca. Furthermore, AlGaN/GaN base HEMTs (high electron mobility transistors) with excellent electron transport properties or like devices have been widely studied as electronic devices using GaN base semiconductors.

Hereinafter, a conventional semiconductor device will be described with reference to accompanying drawings. FIG. 12 is a cross-sectional view of the conventional semiconductor device. More specifically, FIG. 12 illustrates a cross-sectional structure of an AlGaN/GaN base HEMT. As shown in FIG. 12, on a silicon carbide (SiC) substrate 1, a heterojunction layer 2 including a GaN layer as a lower layer and an AlGaN layer as an upper layer is formed. An insulating film (protective insulating film) 3 is formed on the heterojunction layer 2, i.e., on an active region to protect the surface of the heterojunction layer 2. The protective insulating film 3 is a silicon nitride film deposited by, e.g., plasma CVD. In the protective insulating film 3, a plurality of openings are formed so that a gate electrode forming region of the heterojunction layer 2 and a pair of ohmic electrode forming regions of the heterojunction layer 2 which are located to both sides of the gate electrode forming region are exposed through the associated openings. A gate electrode 4 and a pair of ohmic electrodes 5 are formed on the respective parts of the heterojunction layer 2 exposed through the associated openings. The gate electrode 4 is connected to the heterojunction layer 2 by a Schottky junction. Each of the ohmic electrodes 5 is provided at a predetermined distance apart from associated one of both sides of the gate electrode 4 in the gate length direction. One of the ohmic electrodes 5 functions as a source electrode and the other functions as a drain electrode.

In the conventional AlGaN/GaN base HEMT of FIG. 12, parts of the heterojunction layer 2 located between the gate electrode 4 and both of the ohmic electrodes 5 are covered with the protective insulating film 3 of a silicon nitride film. Accordingly, properties of the interface between the GaN base semiconductor layer and the silicon nitride film largely affect electric characteristics of the device.

When the drain current of the conventional AlGaN/GaN base HEMT was measured with high drain voltages applied thereto and then the drain current was measured again for the purpose of examining current-voltage characteristics of the HEMT, it was found that the drain current level largely varied at each measurement, as shown in FIG. 13. That is to say, there arose a problem that the current-voltage characteristics of the HEMT have become unstable. The current-voltage characteristics of the HEMT shown in FIG. 13 were obtained by applying gate voltages (i.e., gate-source voltages) V_{GS} of 0V, −5V, −10V, −15V, and −20V to the HEMT in the reverse direction (so that the gate side has the negative potential). Also, in FIG. 13, the abscissa indicates the drain voltage level (i.e., source-drain voltage level) V_{DS} and the ordinate indicates the drain current level (i.e., source-drain current level) I_{DS} per unit gate width.

A possible cause for the current-voltage characteristics being unstable is, for example, that the drain current is reduced due to traps created at the interface between the GaN base semiconductor layer and the silicon nitride film for protecting the surface of the the GaN base semiconductor layer. It has been also found that the instability of current-voltage characteristics largely depends on types of the protective insulating film, fabrication methods of the protective insulating film (e.g., conditions for performing plasma CVD), or the cleanliness level of the interface between the protective insulating film and the GaN base semiconductor layer in forming the protective insulating film. That is to say, it is very difficult to form a protective insulating film on the surface of a GaN base semiconductor layer without degeneration of electric characteristics of a device.

### SUMMARY OF THE INVENTION

In view of the above described problems, an object of the present invention is to make it possible to form a protective insulating film with excellent interface properties at the interface with a GaN base semiconductor layer, and thereby achieve a highly reliable semiconductor device with stable electric characteristics.

To attain the above-described object, a semiconductor device according to the present invention includes: an active region formed of a Group III nitride semiconductor on a substrate; an electrode formed on the active region; and a protective insulating film formed on part of the active region located in the periphery of the electrode by oxidizing the Group III nitride semiconductor.

In the inventive semiconductor device, the protective insulating film, obtained by oxidizing a Group III nitride semiconductor, i.e., a GaN base semiconductor, is formed on the active region formed of the GaN base semiconductor. Thus, an interface in which defects such as traps are not created and which exhibits excellent properties can be obtained between a GaN base semiconductor layer to be the active region and the protective insulating film. Accordingly, electric characteristics, such as current-voltage characteristics, are stabilized, and thus a semiconductor device with increased reliability can be achieved.

In the inventive semiconductor device, it is preferable that the electrode is a gate electrode, the device further includes a pair of ohmic electrodes formed on parts of the active region located to both sides of the gate electrode, and the protective insulating film is formed on parts of the active region located between the gate electrode and each of the pair of the ohmic electrodes.

Thus, for example, a highly reliable AlGaN/GaN base HEMT with good electric characteristics can be achieved.

In the inventive semiconductor device, it is preferable that the thickness of the protective insulating film is 20 nm or more.

Thus, the active region can be reliably protected.

A first method for fabricating a semiconductor device according to the present invention includes the steps of: forming a semiconductor layer of a Group III nitride semiconductor on a substrate; oxidizing a surface portion of the semiconductor layer and thereby forming a protective insulating film, provided by the oxidized the surface portion, on an active region formed of a non-oxidized portion of the semiconductor layer; and removing a predetermined part of the protective insulating film and then forming an electrode on a part of the active region in which the part of the protective insulating film does not exist.

In the inventive first fabrication method, a surface portion of the Group III nitride semiconductor layer, i.e., a GaN base semiconductor layer, is oxidized so that a protective insulating film, provided by the oxidized surface portion, is formed on an active region formed of a non-oxidized portion of the GaN base semiconductor. . Thus, an interface in which defects such as traps are not created and which exhibits excellent properties can be obtained between the GaN base semiconductor layer to be the active region and the protective insulating film. Accordingly, electric characteristics, such as current-voltage characteristics, are stabilized, and thus a semiconductor device with increased reliability can be achieved.

In the first inventive fabrication method, after the formation of the protective insulating film on the active region, the protective insulating film is partially removed. Thereafter, an electrode is formed on the part of the active region from which the protective insulating film has been removed. Thus, the inventive semiconductor device can be reliably formed in a simple manner.

In the first inventive fabrication method, it is preferable that the step of forming an electrode includes removing parts of the protective insulating film lying on a gate electrode forming region and a pair of ohmic electrode forming regions located to both sides of the gate electrode forming region, and then forming a gate electrode and a pair of ohmic electrodes on a part of the active region located in the gate electrode forming region and on parts of the active region located in the pair of ohmic electrode forming regions, respectively.

Thus, for example, a highly reliable AlGaN/GaN base HEMT with good electric characteristics can be achieved.

A second method for fabricating a semiconductor device according to the present invention includes the steps of forming a semiconductor layer of a Group III nitride semiconductor on a substrate; forming an anti-oxidation film on a predetermined part of the semiconductor layer; oxidizing a surface portion of the semiconductor layer using the anti-oxidation film as a mask and thereby forming a protective insulating film, provided by an oxidized part of the surface portion located outside of the anti-oxidation film, on an active region formed of a non-oxidized portion of the semiconductor layer; and removing the anti-oxidation film and then forming an electrode on a part of the active region from which the anti-oxidation film has been removed.

In the second inventive fabrication method, a surface portion of the Group III nitride semiconductor layer, i.e., a GaN base semiconductor layer, is oxidized so that a protective insulating film, provided by the oxidized surface portion, is formed on an active region formed of a non-oxidized portion of the GaN base semiconductor layer. Thus, an interface in which defects such as traps are not created and which exhibits excellent properties can be obtained between the GaN base semiconductor layer to be the active region and the protective insulating film. Accordingly, electric characteristics, such as current-voltage characteristics, are stabilized, and thus a semiconductor device with increased reliability can be achieved.

In the second inventive fabrication method, with the used of an anti-oxidation film covering a predetermined part of the GaN base semiconductor layer, a protective insulating film, obtained by an oxidized part of a surface portion of the GaN base semiconductor layer located outside of the anti-oxidation film, is formed. Then, the anti-oxidation film is removed and an electrode is formed on a part of the active region from which the anti-oxidation film has been removed. Thus, the inventive semiconductor can be reliably formed. Moreover, since a part of the GaN base semiconductor layer which is to be the active region (more precisely, a part thereof on which an electrode is to be formed) is protected by the anti-oxidation film in oxidizing the surface portion of the GaN base semiconductor layer, it is possible to prevent the active region from being deteriorated due to oxidation. In other words, the part of the GaN base semiconductor layer which is to be the active region can maintain, even after the oxidation, the same structure as it had before the oxidation.

In the second inventive fabrication method, it is preferable that the anti-oxidation film is formed of silicon, silicon oxide, or silicon nitride.

Thus, the predetermined part of the GaN base semiconductor layer can be reliably protected by the anti-oxidation film.

In the second inventive fabrication method, it is preferable that the step of forming an anti-oxidation film includes forming the anti-oxidation film on the semiconductor layer in each a gate electrode forming region and a pair of ohmic electrodes forming regions located to both sides of the gate electrode forming region, and the step of forming an electrode includes removing the anti-oxidation film and then forming a gate electrode and a pair of ohmic electrodes on a part of the active region located in the gate electrode forming region and on parts of the active region located on the pair of ohmic electrode forming regions, respectively.

Thus, for example, a highly reliable AlGaN/GaN base HEMT with good electric characteristics can be achieved.

In the first or second inventive fabrication method, it is preferable that the step of forming a protective insulating film includes subjecting the semiconductor layer to heat treatment in an oxygen atmosphere.

Thus, it is possible to form a protective insulating film, obtained by oxidizing a GaN base semiconductor, with reliability.

### BRIEF DESCRIPTION OF THE DRAWINGS

FIG. 1 is a cross-sectional view of a semiconductor device according to a first embodiment of the present invention.

FIG. 2 is a graph showing current-voltage characteristics for the semiconductor device according to the first embodiment.

FIGS. 3A through 3D are cross-sectional views illustrating respective process steps for fabricating the semiconductor device according to the first embodiment.

FIGS. 4A and 4B are cross-sectional views illustrating respective process steps for fabricating the semiconductor device according to the first embodiment.

FIG. 5 illustrates an exemplary cross-sectional structure of a multilayer body including GaN base semiconductor layers used in a method for fabricating the semiconductor device according to the first embodiment.

FIG. 6 is a graph showing the dependency of the thickness of an oxide layer on time duration of heat treatment, the oxide layer being formed when a GaN layer is subjected to heat treatment at 900° C. in an oxide atmosphere in the method for fabricating the semiconductor device according to the first embodiment.

FIG. 7 is a table showing measurement results of the sheet carrier concentration and carrier mobility of a multilayer body taken before and after heat treatment for forming a protective insulating film in the method for fabricating the semiconductor device according to the first embodiment.

FIG. 8 is a graph showing comparison results for the current-voltage characteristics between the source and the drain in an HEMT structure in which the gate electrode is not yet formed. Comparison was made between an HEMT in which a protective insulating film has been formed by performing thermal oxidation according to the method for fabricating the semiconductor device according to the first embodiment, and an HEMT which has not yet gone through the thermal oxidation and in which a protective insulating film is not yet formed.

FIGS. 9A through 9D are cross-sectional views illustrating respective process steps for fabricating a semiconductor device according to a second embodiment.

FIGS. 10A and 10B are cross-sectional views illustrating respective process steps for fabricating the semiconductor device according to the second embodiment.

FIG. 11 is a graph showing the dependency of etched amount on etching time for each of an anti-oxidation film and a protective insulating film (i.e., oxide layer) when the anti-oxidation film is etched by wet etching using fluoronitric acid in the method for fabricating the semiconductor device according to the second embodiment.

FIG. 12 is a cross-sectional view of a conventional semiconductor device.

FIG. 13 is a graph showing current-voltage characteristics for the conventional semiconductor device.

### DESCRIPTION OF THE PREFERRED EMBODIMENTS

### First Embodiment

Hereinafter, a semiconductor device and a method for fabricating the same according to a first embodiment of the present invention will be described with reference to accompanying drawings.

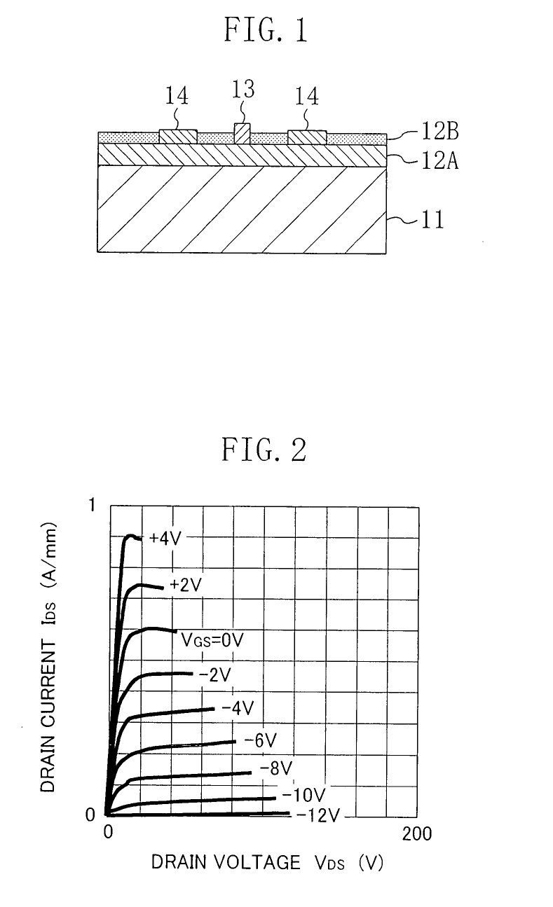

FIG. 1 illustrates the semiconductor device according to the first embodiment of the present invention. More specifically, FIG. 1 illustrates a cross-sectional structure of an HEMT using a GaN base semiconductor.

As shown in FIG. 1, the HEMT of this embodiment includes, a substrate 11 of e.g., SiC, an active region 12A including a GaN base semiconductor layer grown on the substrate 11, and a protective insulating film 12B covering the surface of the active region 12A. The protective insulating film 12B is formed by oxidizing the same GaN base semiconductor as one used for the active region 12A. Moreover, a plurality of openings are formed in the protective insulating film 12B, so that a gate electrode forming region of the active region 12A and a pair of ohmic electrode forming regions of the active region 12A located to both sides of the gate electrode forming region are exposed through the associated openings. A gate electrode 13.and a pair of ohmic electrodes 14 are formed on parts of the active region 12A exposed through respective openings. The gate electrode 13 is connected to the active region 12A by a Schottky junction. That is to say, the gate electrode 13 has a Schottky junction with a GaN base semiconductor layer. Each of the ohmic electrodes 14 is provided at a predetermined distance from an associated one of both sides of the gate electrode 13 in the gate length direction. One of the ohmic electrodes 14 functions as a source electrode and the other functions as a drain electrode.

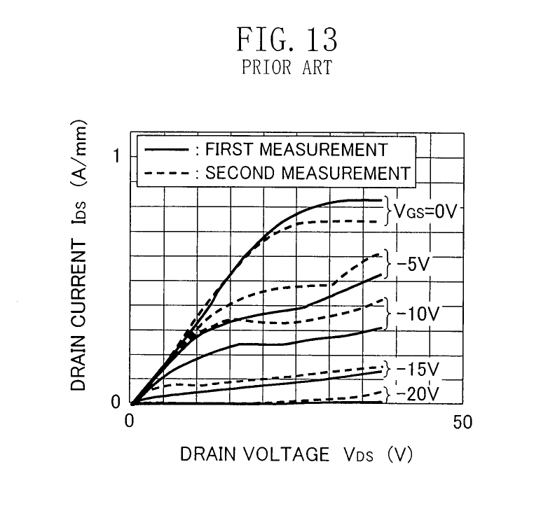

That is to say, the HEMT of this embodiment is characterized in that the active region 12A formed of a non-oxidized portion of the GaN base semiconductor layers is covered by the protective insulating film 12B formed by oxidizing the surface portion of the GaN base semiconductor layer that has been deposited in advance. More specifically, parts of the active region 12A located between the gate electrode 13 and each of the ohmic electrodes 14 are covered by the protective insulating film 12B, obtained by oxidizing a GaN base semiconductor. Therefore, an interface in which defects such as traps are not created and which exhibits excellent properties can be obtained between a GaN base semiconductor layer to be the active region 12A and the protective insulating film 12B. As a result, as shown in FIG. 2, a very stable current-voltage characteristics can be achieved in the HEMT of this embodiment in which the protective insulating film 12B, obtained by oxidizing the GaN base semiconductor, is used, although the current-voltage characteristics are very unstable in the conventional HEMT of FIG. 12 (see FIG. 13) in which a silicon nitride film is used as a protective insulating film for protecting the GaN base semiconductor layer. In other words, when the drain current was measured with high drain voltage applied to the HEMT of this embodiment and then the drain current was measured again, no variation in measurement results, i.e., no variation in the drain current level was observed. Note that the current-voltage characteristics shown in FIG. 2 were obtained by applying gate voltages (i.e., gate-source voltages) V_{GS} of 0V, +2V, and +4V in the forward direction (so that the gate side has the positive potential) and gate voltages V_{GS} of −2V, −4V, −6V, −8V, −10V, and −12V in the reverse direction (so that the gate side has the negative potential) in the HEMT. Also in FIG. 2, the abscissa indicates the drain voltage level (i.e., the source-drain voltage level) V_{DS} and the ordinate indicates the drain current level (i.e., the source-drain current level) I_{DS} per unit gate width.

Hereinafter, the method for fabricating the semiconductor device according to the first embodiment with reference to the accompanying drawings.

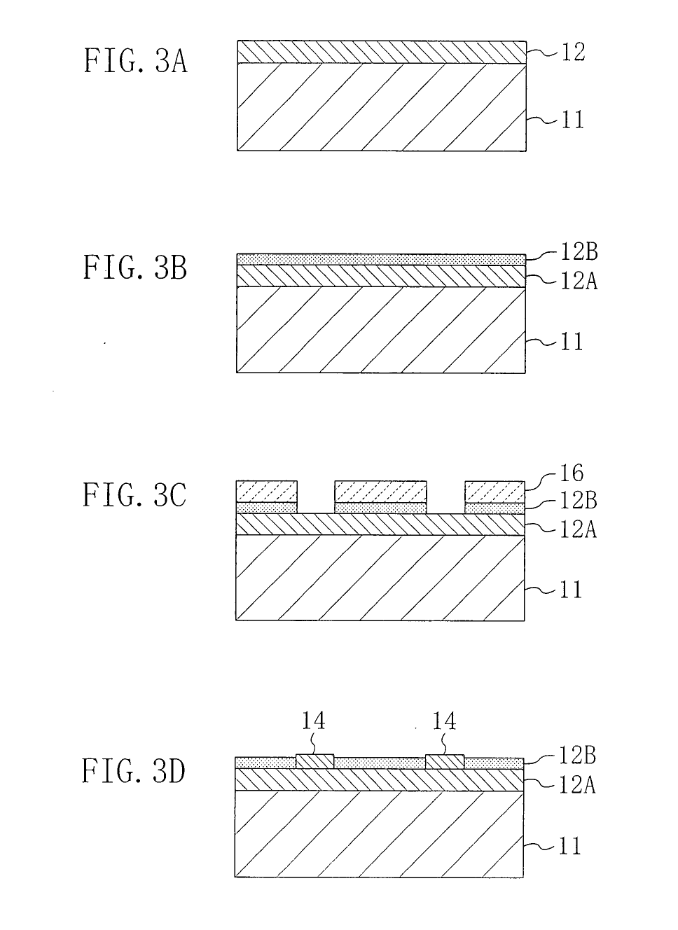

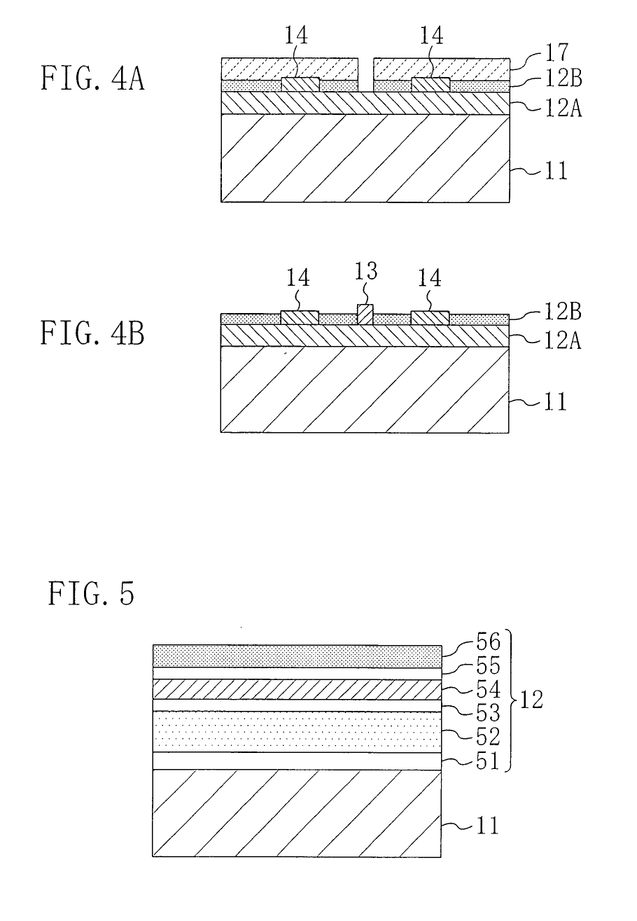

FIGS. 3A through 3D and FIGS. 4A and 4B illustrate fabrication process steps for the semiconductor device according to the first embodiment. More specifically, FIGS. 3A through 3D and FIGS. 4A and 4B are cross-sectional views illustrating respective process steps for fabricating the HEMT of FIG. 1 using the protective insulating film, obtained by oxidizing a GaN base semiconductor.

First, as shown in FIG. 3A, using, e.g., molecular beam epitaxy (which will be hereinafter referred to as “MBE”), a multilayer body 12 in which a plurality of GaN base semiconductor layers are stacked and which includes an AlGaN/GaN heterojunction is formed on a substrate 11 of, e.g., SiC. The detail structure of the multilayer body 12 will be described later.

Next, the multilayer body 12 is subjected to, e.g., heat treatment at about 900° C. for about 20 minutes in an oxygen atmosphere, thereby forming, over the substrate 11, a protective insulating film 12B, obtained by oxidizing the surface portion of the multilayer body 12, on an active region 12A formed from a non-oxidized portion of the multilayer body 12, as shown in FIG. 3B.

Next, as shown in FIG. 3C, using lithography, a first resist pattern 16 having openings corresponding to a pair of ohmic electrode forming regions (i.e., a source electrode forming region and a drain electrode forming region) is formed. Then, the protective insulating film 12B is dry-etched using the first resist pattern 16 as a mask, thereby removing part of the protective insulating film 12B from the ohmic electrode forming regions. In this manner, part of the active region 12A is exposed in each of the ohmic electrode forming regions. Thereafter, using, e.g., evaporation, a multilayer film including, e.g., a Ti film as a lower layer and an Al film as an upper layer is formed over the substrate 11 as well as over the exposed parts of the active region 12A. Then, part of the multilayer film located on the first resist pattern 16 and the first resist pattern 16 is removed by, e.g., lift-off In this manner, as shown in FIG. 3D, a pair of ohmic electrodes 14 one of which is to be as a source electrode and the other of which is to be as a drain electrode is selectively formed on the active region 12A.

Next, as shown in FIG. 4A, using lithography, a second resist pattern 17 having an opening corresponding to a gate electrode forming region located between the ohmic electrodes 14. Then, the protective insulating film 12B is dry-etched using the second resist pattern 17 as a mask, thereby removing part of the protective insulating film 12B from the gate electrode forming region. In this manner, part of the active region 12A is exposed in the gate electrode forming region. Thereafter, using, e.g., evaporation, a multilayer film including, e.g., a Pd film as a lower layer, a Ti film as a middle layer, and an Au film as an upper layer is formed over the substrate 11 as well as over the exposed part of the active region 12A, and then part of the multilayer film located on the second resist pattern 17 and the second resist pattern 17 are removed by, e.g., lift-off. In this manner, as shown in FIG. 4B, a gate electrode 13 is selectively formed on the active region 12A.

Thereafter, although illustrations are omitted, an interlevel insulating film of, e.g., silicon oxide film is formed over the substrate 11 as well as over the gate electrode 13 and each of the ohmic electrodes 14. Then, a plurality of pad electrodes each of which is electrically connected to an associated one of the gate electrode 13 and the ohmic electrodes 14 and includes, e.g., a Ti layer as a lower layer and an Au layer as an upper layer are formed on the interlevel insulating film. With the process steps described above, an AlGaN/GaN base HEMT is completed.

In the first embodiment, the surface portion of the multilayer body 12 including GaN base semiconductor layers is oxidized, so that the protective insulating film 12B, obtained by oxidizing the surface portion, is provided on the active region 12A formed from a non-oxidized portion of the multilayer body 12. Thus, an interface in which defects such as traps are not created and which exhibits excellent properties can be obtained between the GaN base semiconductor layer to be the active region 12A and the protective insulating film 12B. Accordingly, electric characteristics, such as current-voltage characteristics, are stabilized, compared the conventional device in which a silicon nitride film or the like is used as the protective insulating film for protecting the GaN base semiconductor layer. Thus, an HEMT with increased reliability can be achieved.

In the first embodiment, the protective insulating film 12B is formed on the active region 12A and then the protective insulating film 12B is partially removed. Thereafter, each of the electrodes (i.e., the ohmic electrodes 14 and the gate electrode 13) is formed on part of the active region 12A from which part of the protective insulating film 12B has been removed. Thus, the HEMT of this embodiment shown in FIG. 1 can be reliably formed in a simple manner.

Hereinafter, results from an examination of properties of the interface between the GaN base semiconductor layer to be the active region 12A and the protective insulating film 12B, which give a large influence on operating characteristics of an HEMT, will be described.

FIG. 5 illustrates an exemplary cross-sectional structure of the multilayer body 12 used in the examination of interface properties. As shown in FIG. 5, the multilayer body 12 includes: a buffer layer 51 of e.g., AIN and with a thickness of about 100 nm; a channel layer 52 of, e.g., intrinsic GaN and with a thickness of about 3 μm (i.e., 3000 nm); a first barrier layer 53 of, e.g., intrinsic AlGaN and with a thickness of about 2 nm; a second barrier layer 54 of, e.g., n-type AlGaN and with a thickness of about 25 nm; a third barrier layer 55 of, e.g., intrinsic AlGaN and with a thickness of about 3 nm; and an insulating oxide film forming layer 56 of, e.g., GaN and with a thickness of about 20 nm. These layers are grown on the substrate 11 in this order.

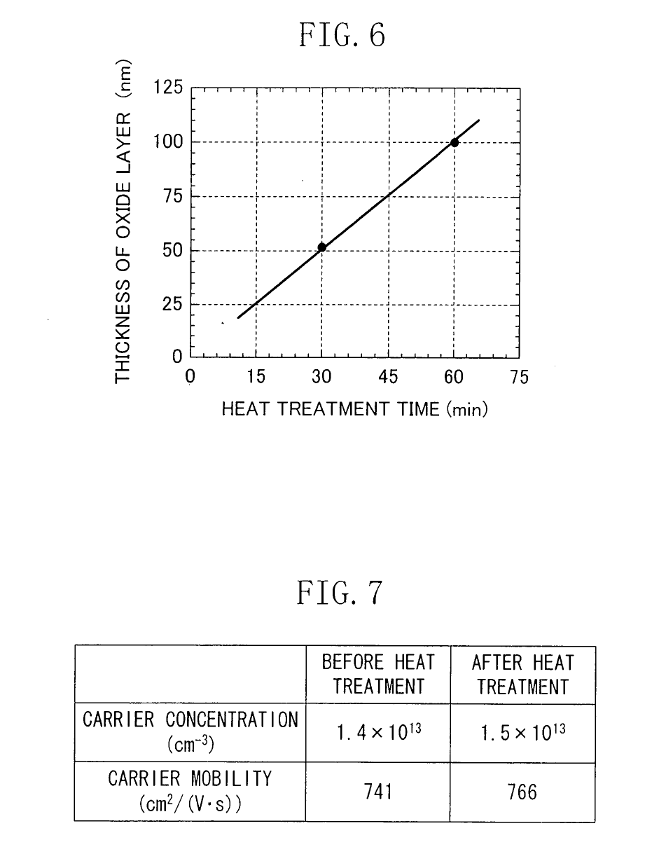

FIG. 6 is a graph showing the dependency of the thickness of an oxide layer (i.e., an insulating oxide film), formed when a GaN layer is subjected to heat treatment at 900° C. in an oxide atmosphere, on time duration of heat treatment. As shown in FIG. 6, when the GaN layer is subjected to the heat treatment for 30 minutes, an oxide layer with an about 50 nm thickness is obtained. When the GaN layer is subjected to the heat treatment for 60 minutes, an oxide layer with an about 100 nm thickness is obtained. It has been found from observations of cross sections of the device with a transmission electron microscope (TEM) that the thickness of an oxide layer formed by the heat treatment is about twice as thick as that of the GaN layer before being subjected to the heat treatment. Accordingly, time required for oxidizing the insulating oxide film forming layer 56, i.e., a GaN layer with a thickness of about 20 nm, is about 20 minutes, and the thickness of the oxide layer (whose main ingredient is Ga₂O₃) formed by oxidizing the insulating oxide film forming layer 56 is about 40 nm. Note that the oxide layer formed by oxidizing the insulating oxide film forming layer 56 corresponds to the protective insulating film 12B and a non-oxidized portion of the multilayer body 12, i.e., the buffer layer 51, the channel layer 52, the first barrier layer 53, the second barrier layer 54, and the third barrier layer 55, corresponds to the active region 12A.

FIG. 7 is a table showing measurement results of the sheet carrier concentration and carrier mobility of the multilayer body 12 before and after the heat treatment. The sheet carrier concentration and carrier mobility are measured by HALL measurements at a room temperature. As shown in FIG. 7, neither the sheet carrier concentration nor the carrier mobility shows large variations before and after the heat treatment, thus indicating no influence by oxidation of the GaN layer (i.e., the insulating oxide film forming layer 56) on the AlGaN layers (i.e., the first barrier layer 53, the second barrier layer 54, and the third barrier layer 55) for supplying electrons.

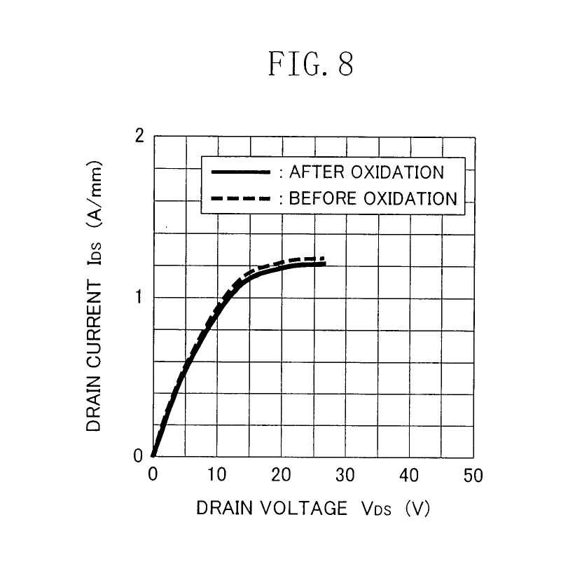

FIG. 8 is a graph showing comparison results for the current-voltage characteristics between the source and the drain in an HEMT structure in which the gate electrode is not yet formed. Comparison was made between an HEMT structure in which the protective insulating film 12B has been formed by subjecting the insulating oxide film forming layer 56, i.e., the surface portion of the multilayer body 12, to thermal oxidation at 900° C. and for 20 minutes in an oxygen atmosphere, and an HEMT structure which has not yet gone through thermal oxidation and in which the protective insulating film 12B has not yet been formed. As shown in FIG. 8, current-voltage characteristics are almost the same before and after the thermal oxidation, thus indicating no influence by thermal oxidation on the active region.

In the first embodiment, the description has been made using an HEMT as an example. However, this embodiment is not limited to HEMTs, but even if other devices, such as field effect transistors (MESFETs), heterojunction bipolar transistors (HBTs), or like devices, are used, the same effects can be attained by forming the protective insulating film, obtained by oxidizing a GaN base semiconductor, on part of the active region of a GaN base semiconductor located in the periphery of each electrode.

In the first embodiment, SiC is used as a material for the substrate 11. However, instead of SiC, other substrate materials, such as sapphire (Al₂O₃), on which a GaN base semiconductor layer can be epitaxially grown may be used.

In the first embodiment, GaN is used as a material for a layer to be oxidized (i.e., the insulating oxide film forming layer 56) for forming the protective insulating film 12B. However, materials for the layer to be oxidized are not limited to GaN, but may includes other GaN base semiconductors, such as AlGaN, InGaN, or InAlGaN, of which a quality insulating oxide layer can be formed. Moreover, in this embodiment, the protective insulating film 12B is formed by subjecting the surface portion of the multilayer body 12 including GaN base semiconductor layers to thermal oxidation, i.e., by subjecting the insulating oxide film forming layer 56 to thermal oxidation. However, instead of thermal oxidation, other techniques by which a quality oxide film with excellent insulation properties can be formed may be used. For example, the protective insulating film 12B may be formed by subjecting the multilayer body 12 to ion implantation, plasma doping, or like techniques.

In the first embodiment, the thickness of the protective insulating film 12B is not particularly limited. However, the thickness of the protective insulating film 12B is preferably 20 nm or more, and, more preferably, 100 nm or more. Thus, the active region 12A can be reliably protected. Moreover, if the thicknesses of the protective insulating film 12B and each of the electrodes (i.e., the gate electrode 13 and the ohmic electrodes 14) are set so that the upper surfaces of the protective insulating film 12B and each of the electrodes are in the same plane, subsequent process steps (e.g., process steps of forming an interlevel insulating film, forming an interconnect, and the like) can be simplified.

In the first embodiment, the protective insulating film 12B is formed over the active region 12A. However, the protective insulating film 12B may be formed only on the parts of the active region 12A located between the gate electrode 13 and each of the ohmic electrodes 14, instead.

In the first embodiment, dry etching is used to remove predetermined parts of the protective insulating film 12B. However, etching techniques are not limited to dry etching, but other etching techniques, such as wet etching using ammonia or the like, may be used.

In the first embodiment, the ohmic electrodes 14 are formed and then the gate electrode 13 is formed. However, instead of the order of forming the electrodes, the gate electrode 13 and the ohmic electrodes 14 may be formed in this order.

### Second Embodiment

Hereinafter, a semiconductor device and a method for fabricating the same according to a second embodiment of the present invention will be described with reference to accompanying drawings.

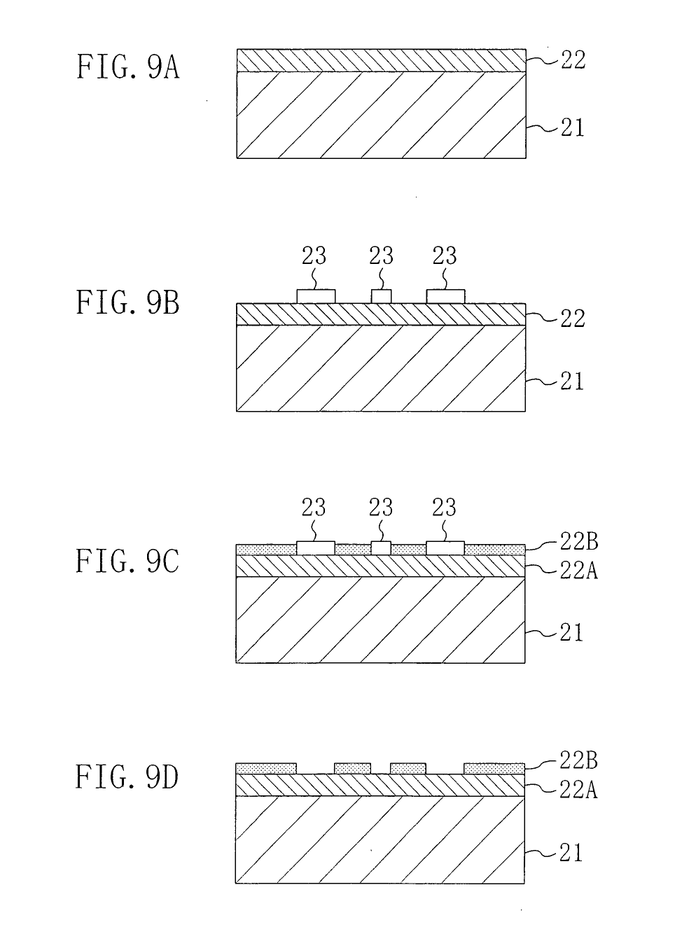

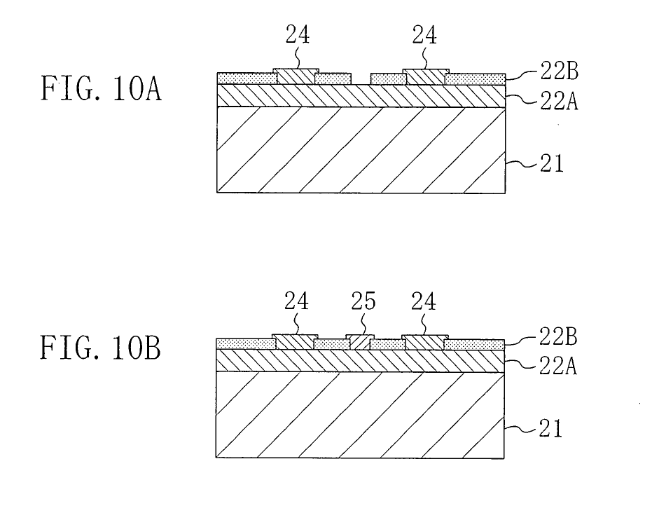

FIGS. 9A through 9D and FIGS. 10A and 10B illustrate fabrication process steps for the semiconductor device according to the second embodiment. More specifically, FIGS. 9A through 9D and FIGS. 10A and 10B are cross-sectional views illustrating respective process steps for fabricating the HEMT using the protective insulating film formed by oxidizing of a GaN base semiconductor.

First, as shown in FIG. 9A, using, e.g., MBE, a multilayer body 22 in which a plurality of GaN base semiconductor layers are stacked and which includes an AlGaN/GaN heterojunction is formed on a substrate 21 of, e.g., SiC. The structure of the multilayer body 22 is the same as that of the multilayer body 12 of the first embodiment (see FIG. 5).

Next, as shown in FIG. 9B, an anti-oxidation film 23 of, e.g., Si (silicon) is formed by, e.g., chemical vapor deposition (CVD), or MBE, on parts of the multilayer body 22 located in a gate electrode forming region and a pair of ohmic electrode forming regions located to both sides of the gate electrode forming region at a predetermined distance apart from the gate electrode forming region.

Next, with the anti-oxidation film 23 still located on the parts of the multilayer body 22, the multilayer body 22 is subjected, e.g., to heat treatment at about 900° C. and for 20 minutes in an oxygen atmosphere. Thus, as shown in FIG. 9C, a protective insulating film 22B, obtained by oxidizing part of the surface portion of the multilayer body 22 located outside of the anti-oxidation film 23, can be formed on an active region 22A formed of a non-oxidized portion of the multilayer body 22.

Next, as shown in FIG. 9D, the anti-oxidation film 23 is removed using, e.g., fluoronitric acid so that the part of active region 22A located in each of the electrode forming regions (i.e., the gate electrode forming region and the pair of ohmic electrode forming regions) is exposed.

Next, as shown in FIG. 10A, using, e.g., evaporation and lithography, a pair of ohmic electrodes 24, one of which is to be a source electrode, the other of which is to be a drain electrode, and each of which includes e.g., a Ti film as a lower layer and an Al film as an upper layer, is selectively formed on the parts of the active region 22A located in the ohmic electrodes forming regions. In this case, each of the ohmic electrodes may be formed so as to extend onto the protective insulating film 22B.

Next, as shown in FIG. 10B, using, e.g., evaporation and lithography, a gate electrode 25 including, e.g., a Pd film as a lower layer, a Ti film as a middle layer, and an Au film as an upper layer is selectively formed on the part of the active region 22A. In this case, the gate electrode 25 may be formed so as to extend onto the protective insulating film 22B.

Thereafter, although illustrations are omitted, an interlevel insulating film of, e.g., silicon oxide film is formed over the substrate 21 as well as over each said ohmic electrodes 24 and the gate electrode 25. Then, a plurality of pad electrodes each of which is electrically connected to an associated one of the ohmic electrodes 24 and the gate electrode 25 and includes, e.g., a Ti film as a lower layer and an Au film as an upper layer are formed on the interlevel insulating film. With the process steps described above, an AlGaN/GaN base HEMT is completed.

In the second embodiment, the surface portion of the multilayer body 22 including GaN base semiconductor layers is oxidized, so that the protective insulating film 22B, obtained by oxidizing the surface portion of the multilayer body 22, is provided on the active region 22A formed from a non-oxidized portion of the multilayer body 22. Thus, an interface in which defects such as traps are not created and which exhibits excellent properties can be obtained between a GaN base semiconductor layer to be the active region 22A and the protective insulating film 22B. Accordingly, electric characteristics, such as current-voltage characteristics, are stabilized, compared to those in the conventional device in which a silicon nitride film or the like is used as the protective insulating film of a GaN base semiconductor layer. Thus, an HEMT with increased reliability can be achieved.

In the second embodiment, the anti-oxidation film 23 covering predetermined parts of the multilayer body 22 including GaN base semiconductor layers is used. Specifically, the protective insulating film 22B, obtained by oxidizing the part of surface portion of the multilayer body 22 located outside of the anti-oxidation film 23, is formed and then the anti-oxidation film 23 is removed. Thereafter, the electrodes (i.e., the ohmic electrodes 24 and the gate electrode 25) are formed on parts of the active region 22A from which the anti-oxidation film 23 has been removed. Thus, the HEMT of this embodiment can be reliably formed. Moreover, when parts of the surface portion of the multilayer body 22 is oxidized, a portion of the multilayer body 22 which is to be the active region 22A (more precisely, a portion thereof on which electrodes are to be formed) is protected by the anti-oxidation film 23. Thus, deterioration of the active region 22A due to the oxidation (i.e., thermal oxidation) can be prevented. In other words, the structure of portion of the multilayer body 22 which is to be the active region 22A before oxidation can be maintained even after the oxidation.

By the way, in the second embodiment, removal of the anti-oxidation film 23 following thermal oxidation for forming the protective insulating film 22B is an important process step. More specifically, if the anti-oxidation film 23 is not completely removed, or if the active region 22A receives a damage in removing the anti-oxidation film 23, transistor characteristics will be degenerated. Furthermore, it is necessary to reliably prevent the protective insulating film 23 from being etched in removing the anti-oxidation film 23.

Then, in the second embodiment, wet etching using fluoronitric acid is performed to remove the anti-oxidation film 23 of Si.

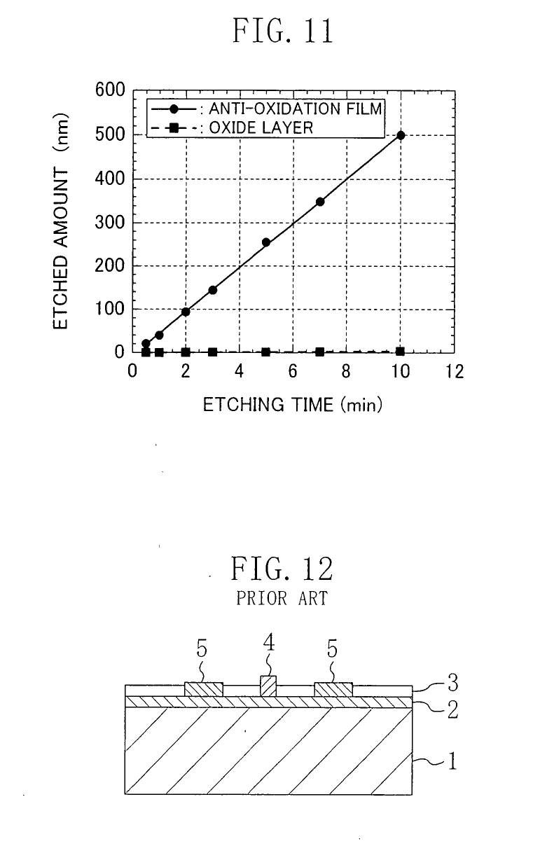

FIG. 11 is a graph showing the dependency of etched amount on etching time for each of the anti-oxidation film 23 and the protective insulating film 22B (i.e., an oxide layer) when the anti-oxidation film is etched by wet etching using fluoronitric acid. As shown in FIG. 11, the anti-oxidation film 23 is easily etched by wet etching using fluoronitric acid while the protective insulating film 23B is hardly etched.

In the second embodiment, the description has been made using an HEMT as an example. However, this embodiment is not limited to HEMTs. Even if other devices, such as MESFETs, HBTs, or like devices, are used, the same effects can be attained by forming a protective insulating film, obtained by oxidizing a GaN base semiconductor, on part of an active region of a GaN base semiconductor located in the periphery portion of each of electrodes.

In the second embodiment, SiC is used as a material for the substrate 21. However, instead of SiC, other substrate materials, such as sapphire, on which a GaN base semiconductor layer can be epitaxially grown may be used.

In the second embodiment, materials for a layer to be oxidized (i.e. the surface portion of the multilayer body 22) for forming the protective insulating film 22B are not particularly limited, as long as they are GaN base semiconductors. For example, materials including AlGaN, InGaN, InAlGaN and the like from which a quality oxide layer can be formed may be used. Moreover, the protective insulating film 22B is formed by subjecting the surface portion of the multilayer body 22 to thermal oxidation in this embodiment. However, instead of thermal oxidation, other techniques by which a quality oxide film with excellent insulation properties can be formed may be used. For example, the protective insulating film 22B may be formed by subjecting the multilayer body 22 to ion implantation, plasma doping, or like techniques.

In the second embodiment, the thickness of the protective insulating film 22B is not particularly limited. However, the thickness of the protective insulating film 22B is preferably 20 nm or more, and, more preferably, 100 nm or more. Thus, the active region 22A can be reliably protected. Moreover, if the thicknesses of the protective insulating film 22B and each of the electrodes (i.e., the ohmic electrodes 24 and the gate electrode 25) are set so that the upper surfaces of the protective insulating film 22B and each of the electrodes are in the same plane, the subsequent process steps (i.e., process steps of forming an interlevel insulating film, forming an interconnect, and the like) can be simplified.

In the second embodiment, the protective insulating film 22B is formed over the active region 22A. However, the protective insulating film 22B may be formed only on the parts of the active region 22A located between the gate electrode 25 and each of the ohmic electrodes 24, instead.

In the second embodiment, wet etching using fluoronitric acid is performed to removed the anti-oxidation film 23. However, instead of such wet etching using fluoronitric acid, wet etching using another etchant or dry etching may be performed.

In the second embodiment, silicon is used as a material for the anti-oxidation film 23. However, materials are not limited to silicon, but other materials which can prevent predetermined parts of the multilayer body 22 (on which the electrodes are to be formed) from being deteriorated due to oxidation, such as thermal oxidation, may be used. For example, silicon oxide, silicon nitride, or the like may be used. When silicon oxide is used as a material for the anti-oxidation film 23, a solution containing hydrofluoric acid such as buffered hydrofluoric acid (BHF) may be used as an etchant for wet-etching the anti-oxidation film 23. As another case, when silicon nitride is used as a material for the anti-oxidation film 23, a solution containing phosphoric acid, such as thermal phosphoric acid, may be used as an etchant for wet-etching the anti-oxidation film 23.

In the second embodiment, the ohmic electrodes 24 are formed and then the gate electrode 25 is formed. However, instead of the order of forming the electrodes, the gate electrode 25 and the ohmic electrodes 24 may be formed in this order.

In the second embodiment, the surface portion of the multilayer body 22 is oxidized using as a mask the anti-oxidation film 23 covering the part of the multilayer body 22 on which each of the electrodes (i.e., the ohmic electrodes 24 and the gate electrode 25) is to be formed, so that the protective insulating film 22B, obtained by oxidizing the part of the surface portion located outside of the anti-oxidation film 23, is formed. However, in the case where sufficient thermostability of each of the electrodes is ensured, instead of performing such process step, a protective insulating film may be formed in the following manner. Without forming the anti-oxidation film, each of the electrodes is formed on the multilayer body before forming the protective insulating film. Then, the surface portion of the multilayer body is oxidized using each of the electrodes as a mask, thereby forming a protective insulating film, obtained by oxidizing part of the surface portion located outside of each of the electrodes.

1-3. (canceled)

4. A method for fabricating a semiconductor device, comprising the steps of:
forming a semiconductor layer of a Group III nitride semiconductor on a substrate;
oxidizing a surface portion of the semiconductor layer and thereby forming a protective insulating film, provided by the oxidized surface portion, on an active region formed of a non-oxidized portion of the semiconductor layer; and
removing a predetermined part of the protective insulating film and then forming an electrode on a part of the active in which the protective insulating film does not exist.

5. The method of claim 4, wherein the step of forming an electrode includes removing parts of the protective insulating film lying on a gate electrode forming region and a pair of ohmic electrode forming regions located to both sides of the gate electrode forming region, and then forming a gate electrode and a pair of ohmic electrodes on a part of the active region located in the gate electrode forming region and on parts of the active region located in the pair of ohmic electrode forming regions, respectively.

6. The method of claim 4, wherein the step of forming the protective insulating film includes subjecting the semiconductor layer to heat treatment in an oxygen atmosphere.

7. A method for fabricating a semiconductor device, comprising the steps of:
forming a semiconductor layer of a Group III nitride semiconductor on a substrate;
forming an anti-oxidation film on a predetermined part of the semiconductor layer;
oxidizing a surface portion of the semiconductor layer using the anti-oxidation film as a mask and thereby forming a protective insulating film, provided by an oxidized part of the surface portion located outside of the anti-oxidation film, on an active region formed of a non-oxidized portion of the semiconductor layer; and
removing the anti-oxidation film and then forming an electrode on a part of the active region from which the anti-oxidation film has been removed.

8. The method of claim 7, wherein the anti-oxidation film is formed of silicon, silicon oxide, or silicon nitride.

9. The method of claim 7, wherein the step of forming an anti-oxidation film includes forming the anti-oxidation film on the semiconductor layer in each of a gate electrode forming region and a pair of ohmic electrodes forming regions located to both sides of the gate electrode forming region, and
wherein the step of forming an electrode includes removing the anti-oxidation film and then forming a gate electrode and a pair of ohmic electrodes on a part of the active region located in the gate electrode forming region and on parts of the active region located in the pair of ohmic electrode forming regions, respectively.

10. The method of claim 7, wherein the step of forming a protective insulating film includes subjecting the semiconductor layer to heat treatment in an oxygen atmosphere.
